(19) United States
(12) Patent Application Publication
(10) Pub. No.: US 2007/0155065 A1
(43) Pub. Date: Jul. 5, 2007

(54) Statistical circuit design with carbon nanotubes

(76) Inventors: Shekhar Y. Borkar, Beaverton, OR (US); Ali Keshavarzi, Portland, OR (US); Juanita K. Kurtin, Hillsboro, OR (US); Vivek K. De, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/323,369

(22) Filed: Dec. 29, 2005

(51) Int. Cl. H01L 21/84; H01L 21/00

(52) U.S. Cl. 438/149

(57) ABSTRACT

Methods and associated structures of forming a microelectronic device are described. Those methods comprise forming a plurality of substantially randomly oriented CNT's on a substrate, and forming at least one source/drain pair, wherein the at least one source/drain pair is coupled to the plurality of substantially randomly oriented CNT's.

### BACKGROUND OF THE INVENTION

Reproducibly fabricating carbon nanotube (CNT) field effect transistors (FET's) that comprise CNTs as channel regions, may be challenging. In some cases, such CNT FET's may possess variable and unreliable circuit characteristics, such as current-voltage characteristics, for example.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1h represent top views of structures according to an embodiment of the present invention.

FIGS. 2a-2e represent cross-sectional views of structures according to an embodiment of the present invention.

FIG. 3 represents a system according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure are described. Those methods may comprise forming a plurality of substantially randomly oriented CNT's on a substrate, forming at least one source/drain on the substrate, wherein the at least one source/drain is coupled to the plurality of substantially randomly oriented CNT's. Methods of the present invention may significantly improve the reproducibility and reliability of a CNT device, such as a CNT FET device, for example.

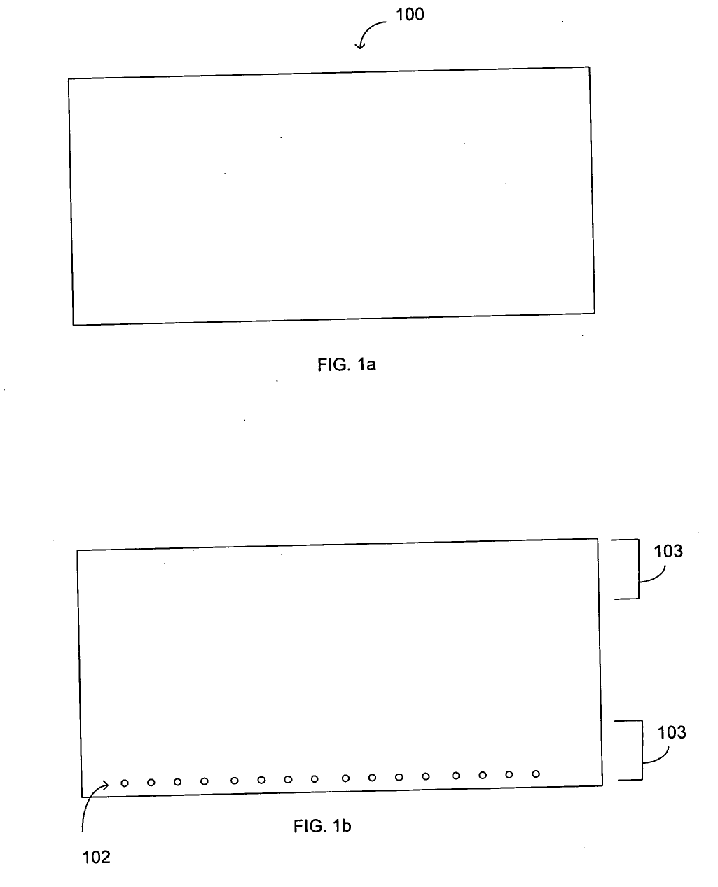

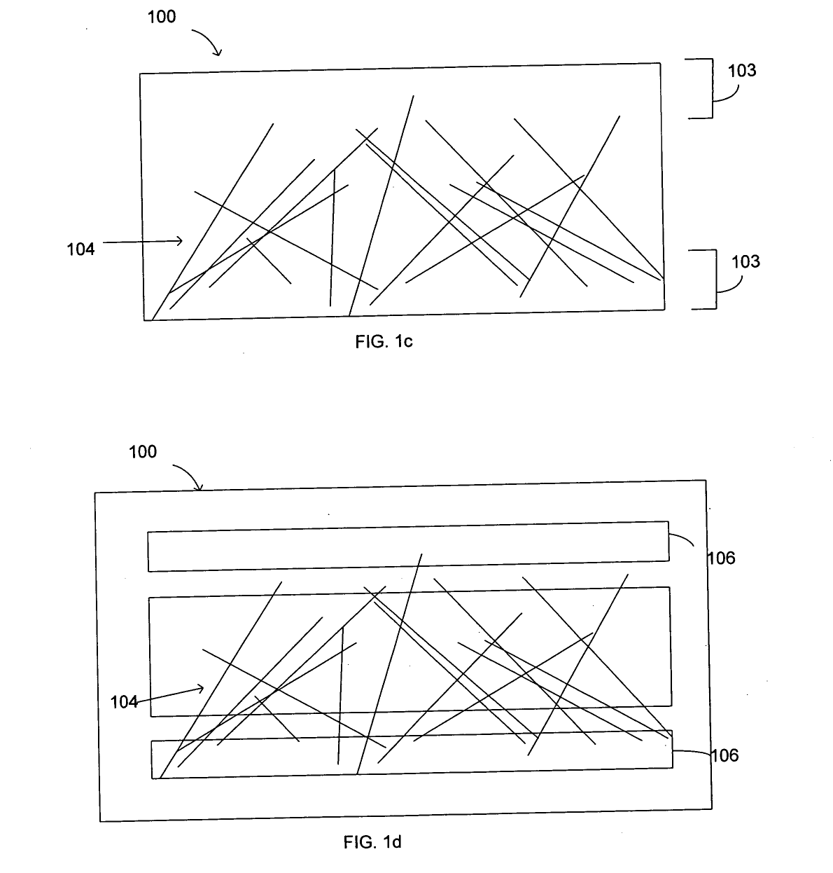

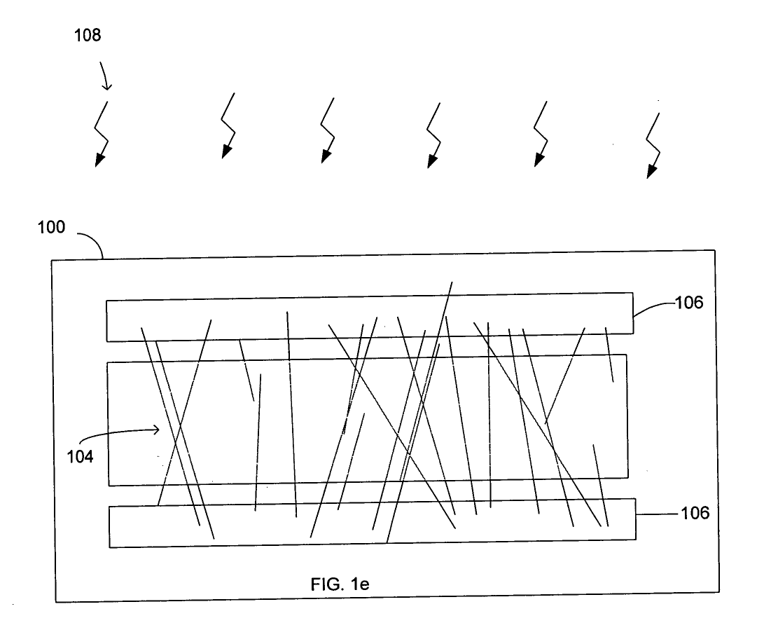

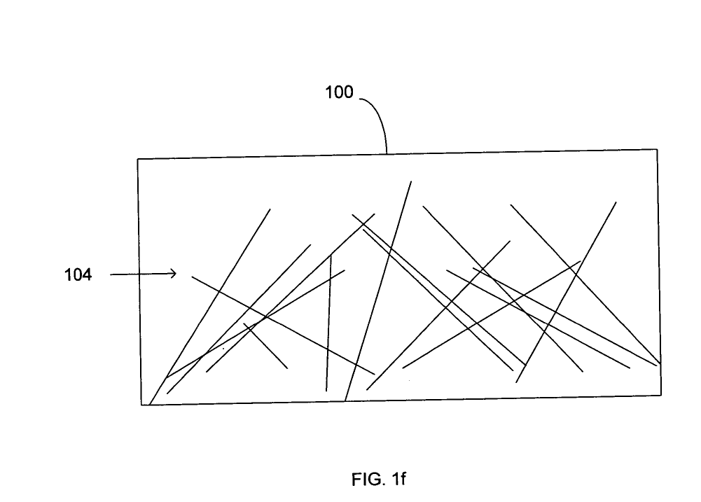

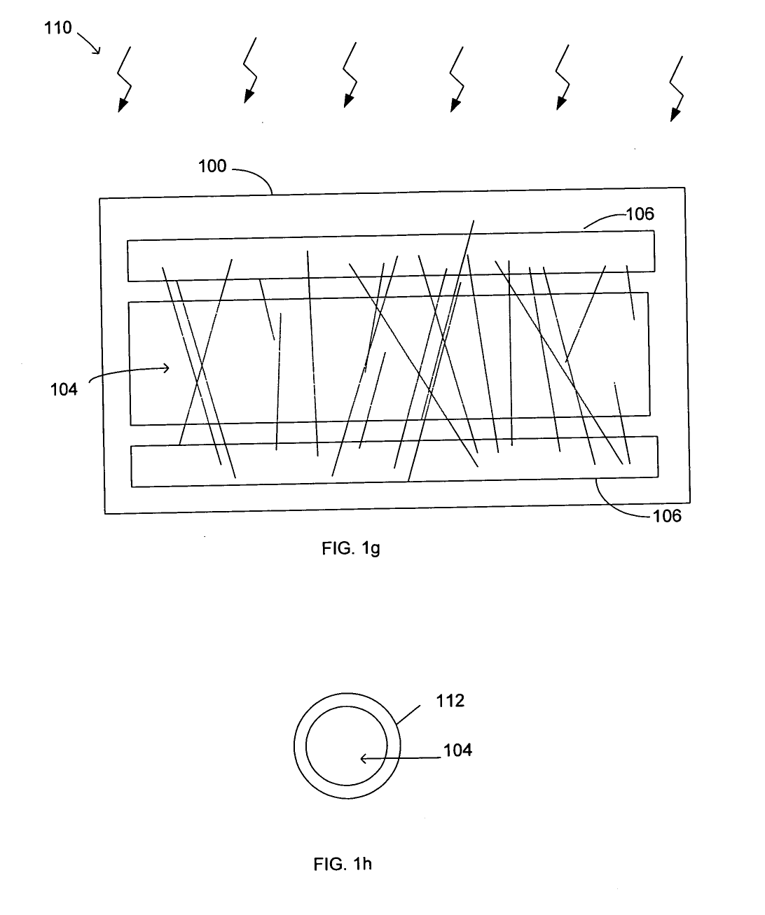

FIGS. 1a-1e illustrate an embodiment of a method and associated structures of forming a microelectronic structure, such as a CNT structure, for example. FIG. 1a illustrates a top view of a portion of a substrate 100 that may comprise a silicon substrate 100 in one embodiment. The substrate 100 may be comprised of materials such as, but not limited to, silicon, silicon-on-insulator, germanium, indium antimonide, lead telluride, indium arsenide, indium phosphide, gallium arsenide, gallium antimonide, or combinations thereof. In one embodiment, the substrate 100 may comprise a substrate of a CNT FET, for example. In another embodiment, the substrate may comprise a p+ backside gate of a CNT FET.

In one embodiment, a plurality of CNT seeds 102 may be placed on the substrate 100 on a source/drain region 103 (FIG. 1b). The plurality of CNT seeds 102 may comprise nickel, carbon, iron, molybdenum, cobalt or other seeds that may be used as catalytic sites for carbon nanotube growth, as is well known in the art. In one embodiment, the plurality of CNT seeds 102 may be used during a chemical vapor deposition (CVD) growth process for carbon nanotube formation. In one embodiment, the CVD process may comprise the following parameters: a temperature of about 900° Celsius for about 7 minutes in a quartz tube furnace at a flow rate of CH₄ of about 1080 ml/min, and a H₂ gas co-flown at a rate of about 125 ml/min (Franklin, Li, Chen, Javey, and Dai, Applied Physics letters, v.79 no 27 pg 4571,2001).

In one embodiment, the plurality of CVD seeds 102 may be placed and patterned in the source/drain region 103, where one of either a source or a drain feature of a CNT FET will be patterned from a portion of the substrate 100, during a subsequent process step. The CNTs may also be grown off-substrate and assembled on the substrate by chemical methods such as spinning or fluidic flow, which would not require the use of patterned seeds. The number of the plurality of CNT seeds 102 that may be placed on the substrate 100 may vary depending upon the particular application, but in some embodiments the number of the plurality of CNT seeds 102 may comprise a substantially repeatable statistical number. For example, in some cases, approximately 10 percent of the CNT tubes that grow from the plurality of CNT seeds 102 may comprise metallic CNTs. The remaining 90 percent may comprise semiconducting CNTs. The semiconducting CNTs may comprise a mixture of diameters and chiralities, and in some embodiments may comprise a diameter between about 0.8 and 1.5 nm.

Microelectronic devices, such as circuits utilizing CNT FETS (which utilize CNTs as a channel structure within the device), may be designed that comprise such a mixture of diameters, orientations, and metallic CNTs as long as the number of non-semiconducting CNTs is substantially known, and substantially repeatable. Thus, on average, a device that may use a larger number of the plurality of CNT seeds 102 may yield more statistically repeatable percentages of metallic CNTs, than a device using smaller number of the plurality of CNT seeds 102. In this manner, circuits may be designed to accommodate and/or offset the effects of such non-semiconducting CNTs for a particular device.

In one embodiment, utilizing about 100 CNT seeds may be yield a more repeatable device, since the device effects of the metallic CNTs may be averaged out over a larger, more statistically significant sample size (number of plurality of CNT seeds 102) as compared with a smaller sample size (such as in the case of 4 CNT seeds being used), In this manner, any off-state leakage that may be contributed by the metallic CNTs within such a CNT device may be substantially averaged out over a larger number of CNT's, and thus such leakage may be more repeatable, predictable, and manageable within the device. In one embodiment, the substantially repeatable statistical number of the plurality of CNT seeds that may be utilized may comprise about 50 to about 200 CNTs. I none embodiment, in the case of CNTs placed on a substrate by chemical methods rather than in-situ CVD growth, controlling the density of tubes per unit width during placement would achieve the same goals as controlling the number of catalytic seeds.

In one embodiment, a plurality of substantially randomly oriented CNTs 104 may be grown on the substrate 100 (FIG. 1c). In one embodiment, the plurality of substantially randomly oriented CNT's 104 may comprises about 90 percent semiconducting CNT's, and about 10 percent metallic CNTs. The number of the plurality of substantially randomly oriented CNT's 104 that may comprise metallic CNT's may vary, depending upon formation process parameters, etc. The plurality of substantially randomly oriented CNTs 104 may lie across the substrate in a substantially random orientation because in some cases, CNTs may not grow in a substantially aligned manner. Consequently, as the plurality of substantially randomly oriented CNTs 104 grow, some will not extend across to the edges of the substrate 100.

In one embodiment, the plurality of substantially randomly oriented CNT's 104 may comprises about 90 percent semiconducting CNT's, and about 10 percent metallic CNTs. The plurality of substantially randomly oriented CNTs 104 may lie across the substrate in a substantially random orientation because CNTs in general do not grow in a substantially aligned manner. Consequently, as the plurality of substantially randomly oriented CNTs 104 grow, some will not extend across to the edges of the substrate 100.

The plurality of substantially randomly oriented CNTs 104 may comprise many crossings between individual CNTs, and there may also be many places where some of the CNTs do not make it all the way across the substrate 100. CNT crossings may create a scattering event for the electrical carriers (electrons or holes) of a device utilizing such a channel structure, so minimizing these crossings may enhance device performance. In one embodiment, CVD process parameters may be optimized to minimize the amount of CNT crossings and maximize the number of CNTs that may extend across the substrate.

In one embodiment, at least one source/drain pair 106 may be patterned from and/or formed on the source/drain region 103 of the substrate 100 using lithographic processing as is well known in the art (FIG. 1d). The source/drain pair 103 may comprise various materials, such as doped silicon and/or conductive material, for example. In one embodiment, a portion of the plurality of substantially randomly oriented CNT's 104 may be electrically coupled to the at least one source/drain pair 106. In one embodiment, in order to increase the number of the plurality of substantially randomly oriented CNT's 104 that may electrically couple and extend between the at least one source/drain pair, the plurality of substantially randomly oriented CNT's 104 may be substantially aligned across the substrate 100.

An alignment process 108 may comprise at least one of a gas flow or an electric field to substantially align the plurality of substantially randomly oriented CNT's 104 to be oriented between the at least one source/drain pair (FIG. 1e). The alignment technique may be optimized to improve device performance, depending upon the particular application.

In another embodiment, the plurality of substantially randomly oriented CNTs 104 may be placed on the substrate 100 by employing a spin on method, as is known in the art. (FIG. 1f). In one embodiment, a plurality of CNTs may be stablilized in liquids by sonicating with surfactants, which may wrap the CNTs. In one embodiment, the CNTs may then be separated out, placed on the substrate 100 and semi-aligned across the substrate 100 utilizing various alignment processes 110, such as a liquid based process including but not limited to electrophoresis, for example (FIG. 1g). A portion of the plurality of substantially randomly oriented CNTs 104 may be electrically coupled to the at least one source/drain pair 106.

Aligning the plurality of substantially randomly oriented CNTs 104 may substantially reduce the amount of crossings between the plurality of substantially randomly oriented CNTs 104 and thus may reduce carrier scattering within a CNT device that may utilize embodiments of the present invention. In one embodiment, the plurality of substantially randomly oriented CNTs 104 may comprise a suitable dielectric coating 112 that in some instances may reduce tube-to-tube interactions and improve the gate control of such a CNT device (FIG. 1h).

In one embodiment, both PMOS and NMOS CNT devices can be made by altering the electronegativity of the dielectric coating 112. For example, by using an electron-donating material, the plurality of substantially randomly oriented CNTs 104 may become n-type. This method could be used to dope both “spun-on” or CVD grown tubes.

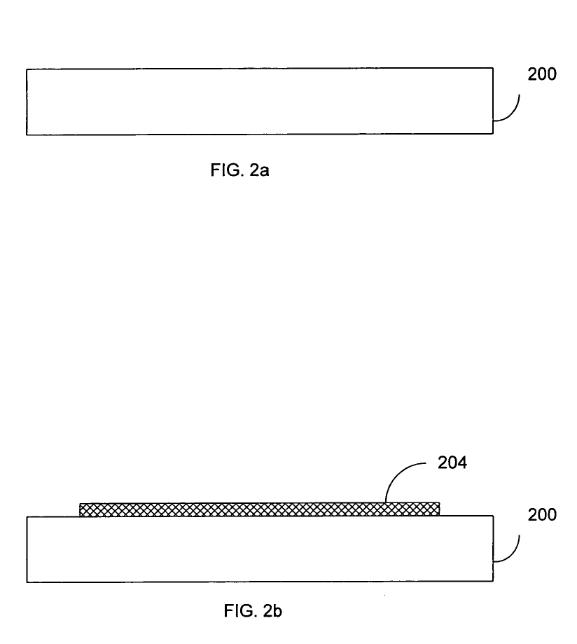

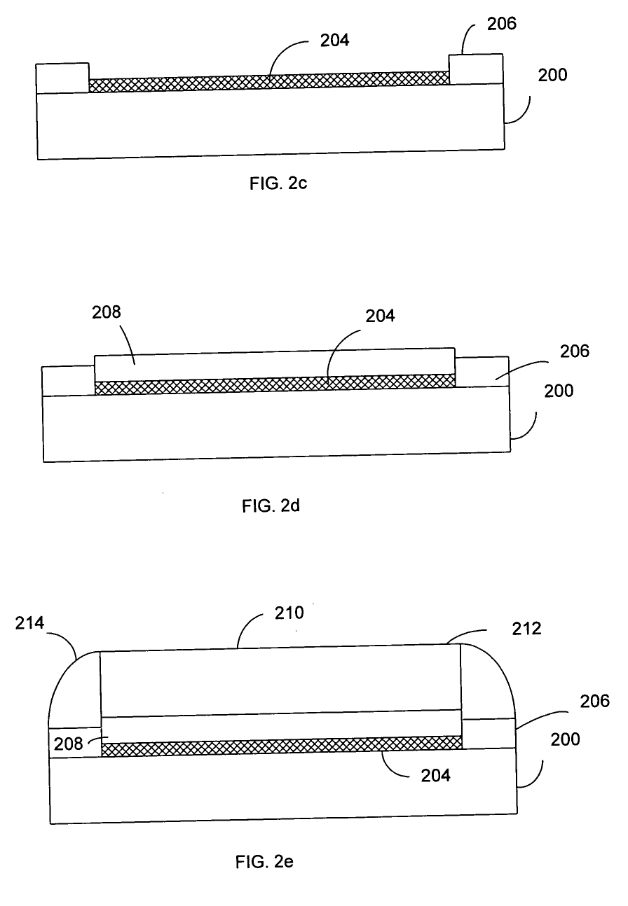

FIGS. 2a-2e depict a device that may be formed according to embodiments of the present invention. In one embodiment (FIG. 2a), a substrate 200 may be comprised of materials such as, but not limited to, silicon, silicon-on-insulator, germanium, indium antimonide, lead telluride, indium arsenide, indium phosphide, gallium arsenide, gallium antimonide, or combinations thereof. In one embodiment, the substrate 200 may be doped with p-type dopant, as are well known in the art. In one embodiment, the substrate 200 may comprise a p+ backside gate of a FET device, for example. In one embodiment, the p+ backside gate may be silicon heavily doped with a p-type dopant, such as boron, for example, as is well known in the art.

In one embodiment, a plurality of substantially randomly oriented CNTs 204 (similar to the plurality of substantially randomly oriented CNTs 104 of FIG. 1c, for example) may be placed and/or formed on the substrate 200 (FIG. 2b). In one embodiment, the plurality of substantially randomly oriented CNTs 204 may be formed by a CVD process (as described above) utilizing a plurality of CNT seeds. In another embodiment, the plurality of substantially randomly oriented CNTs 204 may be placed and/or deposited utilizing a spin-on process, as previously described herein.

In some embodiments, the plurality of substantially randomly oriented CNTs 204 may comprise at least one single walled CNT, and may comprise about 90 percent semiconducting CNTs. In one embodiment, at least one source/drain pair 206 may be formed on the substrate and may be electrically coupled to the plurality of substantially randomly oriented CNTs 204 (FIG. 2c). In one embodiment, the at least one source/drain pair 206 may be patterned using any suitable patterning technique, such as lithographic techniques, for example. It will be understood by those skilled in the art that at least one source/drain pair 206 may be formed prior to the formation and/or placing of the plurality of substantially randomly oriented CNTs 204 on the substrate 200, depending upon the particular application.

A gate dielectric 208 may be formed on the plurality of substantially randomly oriented CNTs 204 and on the at least one source/drain pair 206 (FIG. 2d). The gate dielectric 208 may comprise a silicon dioxide layer or high k gate dielectric material, in some embodiments. In one embodiment, the gate dielectric 208 may comprise metal oxides such as hafnium oxide and/or lanthanum oxide, zirconium oxide, titanium oxide, and aluminum oxide for, example. In one embodiment, the gate dielectric 208 may have a thickness from about 10 Angstroms to about 150 Angstroms. In one embodiment, the gate dielectric 208 may comprise a dielectric material comprising a dielectric constant greater than about 10.

A gate electrode 210 may be disposed on the gate dielectric 208, thus forming a CNT device 212. The gate electrode 210 may comprise a metal gate electrode in one embodiment, or a polysilicon gate electrode in other embodiments. In one embodiment, the plurality of substantially randomly oriented CNTs 204 may form a channel region of the CNT device 212, such as a CNT FET device, for example. In one embodiment, the CNT device may comprise at least one spacer 214.

By fabricating the CNT device 212 comprising a channel region comprised of the plurality of substantially randomly oriented CNTs 204 coupled to at least one source/drain pair 206, such a device may, on average, comprise current-voltage (I-V) characteristics that may be more reproducible and reliable than a CNT device relying on a single, or even a small array of only a few CNTs. Such a device may comprise overall, averaged out transistor I-V characteristics. Such a device would not need to rely on tightly controlled patterning of a well-aligned, uniformly spaced array of single diameter semconducting CNTs. Such a CNT device may be used as a building block transistor for various digital and analog circuits, according to a particular application.

For example, functional circuits may be built utilizing the CNT device of the embodiments of the present invention that may comprise p-type Shottky Barrier (SB) CNT FETs, as are known in the art. In some embodiments, the work function of a metal gate electrode of the P-type SB CNT FETS may be shifted to improve the Flat Band voltage of such a CNT FET. In this manner, the amount of current at off-state at VG=OV may be minimized. This shifting of the work function may serve to maximize Ion to loff ratio for this transistor type.

Ratio-ed logic may also be utilized to build adders, multipliers, and other circuits and systems comprising only P-type CNT FET transistors, for example. Analog circuits may be enabled by utilizing CNT devices of the embodiments of the present invention, since larger pluralities of channel CNT's on average, comprise current-voltage (I-V) characteristics that are more reproducible and reliable than using smaller arrays of CNTs as device channels.

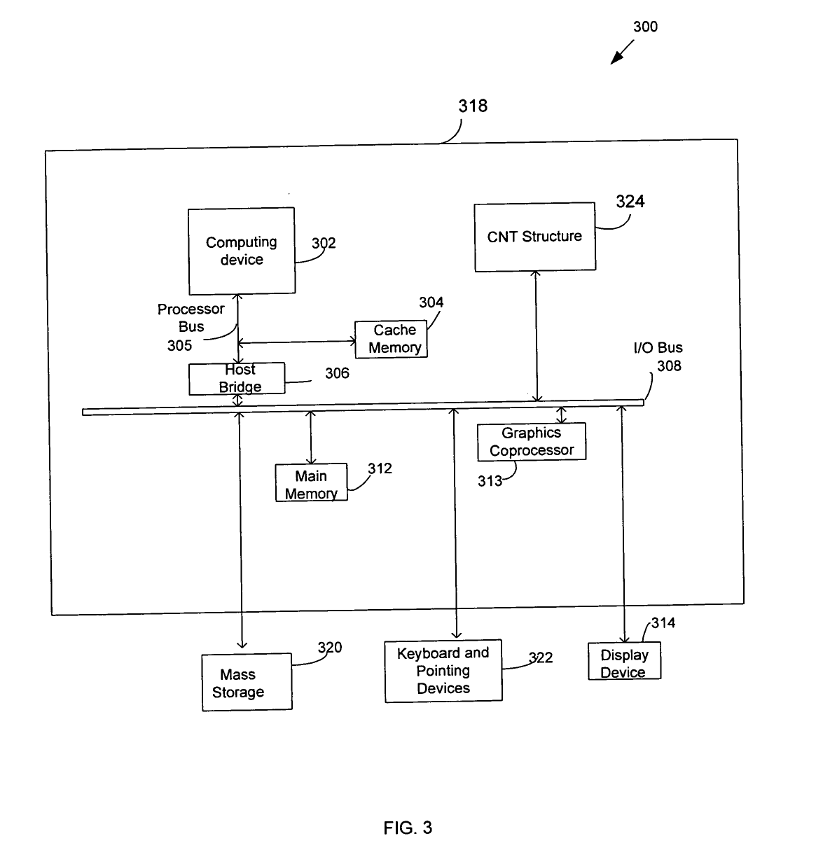

29 FIG. 3 is a diagram illustrating an exemplary system 300 capable of being operated with methods for fabricating a microelectronic structure, such as the CNT structure of FIG. 2e, for example. It will be understood that the present embodiment is but one of many possible systems in which the substrate core structures of the present invention may be used.

In the system 300, the CNT structure 324 may be communicatively coupled to a printed circuit board (PCB) 318 by way of an I/O bus 308. The communicative coupling of the CNT structure 324 may be established by physical means, such as through the use of a package and/or a socket connection to mount the CNT structure 324 to the PCB 318 (for example by the use of a chip package, interposer and/or a land grid array socket). The CNT structure 324 may also be communicatively coupled to the PCB 318 through various wireless means (for example, without the use of a physical connection to the PCB), as are well known in the art.

The system 300 may include a computing device 302, such as a processor, and a cache memory 304 communicatively coupled to each other through a processor bus 305. In one embodiment, the computing device 302 may comprise at least one CNT structure, similar to the CNT structure 124, for example. The processor bus 305 and the I/O bus 308 may be bridged by a host bridge 306. Communicatively coupled to the I/O bus 308 and also to the CNT structure 324 may be a main memory 312. Examples of the main memory 312 may include, but are not limited to, static random access memory (SRAM) and/or dynamic random access memory (DRAM), and/or some other state preserving mediums. In one embodiment, the main memory 312 may comprise at least one CNT structure, similar to the CNT structure 124, for example. The system 300 may also include a graphics coprocessor 313, however incorporation of the graphics coprocessor 313 into the system 300 is not necessary to the operation of the system 300. Coupled to the I/O bus 308 may also, for example, be a display device 314, a mass storage device 320, and keyboard and pointing devices 322.

These elements perform their conventional functions well known in the art. In particular, mass storage 320 may be used to provide long-term storage for the executable instructions for a method for forming and/or utilizing CNT structures in accordance with embodiments of the present invention, whereas main memory 312 may be used to store on a shorter term basis the executable instructions of a method for forming and/or utilizing CNT structures in accordance with embodiments of the present invention during execution by computing device 302. In addition, the instructions may be stored, or otherwise associated with, machine accessible mediums communicatively coupled with the system, such as compact disk read only memories (CD-ROMs), digital versatile disks (DVDs), and floppy disks, carrier waves, and/or other propagated signals, for example. In one embodiment, main memory 312 may supply the computing device 302 (which may be a processor, for example) with the executable instructions for execution.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic devices, such as a FET, are well known in the art. Therefore, it is appreciated that the Figures provided herein illustrate only portions of an exemplary microelectronic device that pertains to the practice of the present invention. Thus the present invention is not limited to the structures described herein.

What is claimed is:

1. A method comprising:
forming a plurality of substantially randomly oriented CNT's on a substrate;
forming at least one source/drain pair on the substrate, wherein the at least one source/drain pair is electrically coupled to the plurality of substantially randomly oriented CNT's.

2. The method of claim 1 wherein the plurality of substantially randomly oriented CNT's comprises about 90 percent semiconducting CNT's.

3. The method of claim 1 wherein forming a plurality of substantially randomly oriented CNT's comprises forming a plurality of substantially randomly oriented CNT's by chemical vapor deposition.

4. The method of claim 3 wherein forming the plurality of substantially randomly oriented CNT's comprises placing a plurality of CNT seeds on a source/drain region and then growing the plurality of substantially randomly oriented CNT's from the plurality of CNT seeds.

5. The method of claim 4 further comprising coupling the plurality of substantially randomly oriented CNT's between the source/drain pair by semi-aligning the plurality of CNT's by at least one of the application of an electric field and the application of a gas flow.

6. The method of claim 1 wherein the plurality of substantially randomly oriented CNT's comprises a channel region of a CNT device.

7. The method of claim 1 wherein forming the plurality of substantially randomly oriented CNT's comprises placing the plurality of substantially randomly oriented CNT's by a spin on process.

8. The method of claim 7 further comprising semi-aligning the plurality of substantially randomly oriented CNT's by electrophoresis.

9. The method of claim 1 wherein forming the plurality of substantially randomly oriented CNT's comprises forming a substantially repeatable statistical number of substantially randomly oriented CNT's.

10. The method of claim 9 wherein forming the substantially repeatable statistical number of substantially randomly oriented CNT's comprises forming between about 50 to about 200 substantially randomly oriented CNT's.

11. A method of forming a CNT device comprising:
forming a plurality of substantially randomly oriented CNT's on a substrate;
forming at least one source/drain pair, wherein the plurality of substantially randomly oriented CNT's form a channel region between the at least one source/drain pair; and
forming a gate dielectric on the at least one source/drain pair.

12. The method of claim 10 further comprising forming a gate electrode on the gate dielectric.

13. The method of claim 12 wherein forming the gate electrode comprises forming a metallic gate electrode.

14. The method of claim 10 wherein forming the plurality of substantially randomly oriented CNT's further comprises wherein the substantially randomly oriented CNT's comprise a dielectric coating.

15. The method of claim 10 wherein the dielectric coating comprises at least one of a p type dielectric coating and an n-type dielectric coating.

16. A structure comprising:
a plurality of substantially randomly oriented CNT's disposed on a substrate; and
at least one source/drain pair, wherein the at least one source/drain pair is coupled to the plurality of CNT's.

17. The structure of claim 16 wherein the plurality of substantially randomly oriented CNT's comprise about 90 percent semiconducting CNT's.

18. The structure of claim 16 wherein the plurality of substantially randomly oriented CNT's comprises a channel region of a CNT device.

19. The structure of claim 16 further comprising a gate dielectric disposed on the plurality of substantially randomly oriented CNT's.

20. The structure of claim 16 further comprising a gate electrode disposed on the gate dielectric.

21. The structure of claim 16 wherein the number of the plurality of substantially randomly oriented CNT's comprise about 50 to about 200 CNT's.

22. The structure of claim 16 wherein the substantially randomly oriented CNT's comprises a dielectric coating.

23. The structure of claim 16 wherein the polymer dielectric coating comprises at least one of a p-type dielectric coating and an n-type dielectric coating.

24. The structure of claim 16 wherein gate dielectric comprises a dielectric constant greater than about 10.

25. The structure of claim 16 wherein structure comprises a CNT FET.

26. A system comprising:
a CNT device comprising:
a plurality of substantially randomly oriented CNT's disposed on a substrate; and
at least one source/drain pair, wherein the at least one source/drain pair is electrically coupled to the plurality of CNT's;
a bus communicatively coupled to the CNT device; and
a DRAM communicatively coupled to the bus.

27. The system of claim 26 wherein the plurality of substantially randomly oriented CNT's comprise about 90 percent semiconducting CNT's.

28. The system of claim 26 wherein the plurality of substantially randomly oriented CNT's comprises a channel region of the CNT device.

29. The system of claim 26 further comprising a gate dielectric disposed on the plurality of substantially randomly oriented CNT's.
